(19) United States
(12) Patent Application Publication
(10) Pub. No.: US 2025/0316565 A1
(43) Pub. Date: Oct. 9, 2025

(54) DEVICE PACKAGE HAVING SIGNAL PADS CONFIGURED TO PROMOTE SELF ALIGNMENT OF LEADS AND PROCESS OF IMPLEMENTING THE SAME

(71) Applicant: MACOM TECHNOLOGY SOLUTIONS HOLDINGS, INC., Lowell, MA (US)

(72) Inventors: Sung Chul JOO, Cary, NC (US); Benjamin LAW, Fremont, CA (US); Javier LEYVA, Los Banos, CA (US); Gordon CHONG, South San Francisco, CA (US); Ben GAU, Fremont, CA (US)

(21) Appl. No.: 18/629,726

(22) Filed: Apr. 8, 2024

(51) Int. Cl. H01L 23/495; H01L 21/48

(52) U.S. Cl. CPC H01L 23/49524; H01L 21/4825; H01L 23/49575

(57) ABSTRACT

A device package includes a plurality of leads comprising lead structures configured as part of a leadframe during manufacturing. The plurality of leads include attachment pads and a lead alignment construction comprising one or more of the attachment pads being implemented with a solder mask material configured to promote alignment of all of the plurality of leads attached to the leadframe during solder reflow.

### FIELD OF THE DISCLOSURE

The disclosure relates to a device package having pads configured to promote self alignment of leads. Additionally, the disclosure relates to a process of implementing a device package having pads configured to promote self alignment of the leads.

### BACKGROUND OF THE DISCLOSURE

Many device packages implement leads that are configured to be attached to pads. Typically the attachment is implemented with a solder reflow process. However, during the solder reflow process, leads may become misaligned with the pads.

Accordingly, a device and process are needed to reduce misalignment between pads and leads.

### SUMMARY OF THE DISCLOSURE

The foregoing needs are met, to a great extent, by the disclosure, wherein in one aspect a device package having pads configured to promote self alignment of leads is provided. Additionally, the foregoing needs are met, to a great extent, by the disclosure, wherein a process of implementing a device package having pads configured to promote self alignment of leads.

In one aspect, a device package includes a plurality of leads having lead structures configured as part of a leadframe during manufacturing. The device package in addition includes the plurality of leads may include attachment pads. The package moreover includes a lead alignment construction having one or more of the attachment pads being implemented with a solder mask material configured to promote alignment of all of the plurality of leads attached to the leadframe during solder reflow.

In one aspect, a process includes configuring a plurality of leads having lead structures as part of a leadframe during manufacturing. The process in addition includes configuring the plurality of leads with attachment pads. The process moreover includes configuring a lead alignment construction having one or more of the attachment pads being implemented with a solder mask material configured to promote alignment of all of the plurality of leads attached to the leadframe during solder reflow.

There has thus been outlined, rather broadly, certain aspects of the disclosure in order that the detailed description thereof herein may be better understood, and in order that the present contribution to the art may be better appreciated. There are, of course, additional aspects of the disclosure that will be described below and which will form the subject matter of the claims appended hereto.

In this respect, before explaining at least one aspect of the disclosure in detail, it is to be understood that the disclosure is not limited in its application to the details of construction and to the arrangements of the components set forth in the following description or illustrated in the drawings. The disclosure is capable of aspects in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the disclosure. It is important, therefore, that the claims be regarded as including such equivalent constructions insofar as they do not depart from the spirit and scope of the disclosure.

### BRIEF DESCRIPTION OF THE DRAWINGS

FIG. 1 illustrates a device package according to aspects of the disclosure.

FIG. 2 illustrates another device package according to aspects of the disclosure.

FIG. 3 illustrates partial details of the device package and one of the leads implementing a lead alignment construction according to FIG. 1 and/or FIG. 2.

FIG. 4 illustrates further details of one of the leads having the lead alignment construction according to FIG. 3.

FIG. 5 illustrates another implementation of one of the leads having the lead alignment construction according to aspects of the disclosure.

FIG. 6 illustrates another implementation of one of the leads having the lead alignment construction according to aspects of the disclosure.

FIG. 7 illustrates partial details of the device package and one of the leads not implementing the lead alignment construction according to FIG. 1 and/or FIG. 2.

FIG. 8 illustrates partial details of the device package and one of the leads not implementing the lead alignment construction according to FIG. 1 and/or FIG. 2.

FIG. 9 illustrates partial details of the device package prior to solder reflow according to aspects of the disclosure.

FIG. 10 illustrates partial details of the device package after solder reflow according to FIG. 9.

FIG. 11 illustrates another device package according to aspects of the disclosure.

FIG. 12 illustrates another device package according to aspects of the disclosure.

FIG. 13 illustrates another device package according to aspects of the disclosure.

FIG. 14 illustrates another device package according to aspects of the disclosure.

FIG. 15 illustrates an exemplary process of forming leads on a device package according to aspects of the disclosure.

### DETAILED DESCRIPTION

The disclosure will now be described with reference to the drawing figures, in which like reference numerals refer to like parts throughout. Aspects of the disclosure advantageously provide a device package having pads configured to promote self alignment of leads. Additionally, aspects of the disclosure advantageously provide a process of implementing a device package having pads configured to promote self alignment of leads.

In a device package, leads have to be aligned for subsequent connection with corresponding connection features of a component. For example, device packages implemented as radio frequency (RF) devices need to have leads aligned with connection features in a test fixture, a transmission system, and/or the like. In aspects, both the leads and the pads may be metallic.

With respect to the device package, a common cause for lead misalignment is an off-center lead attach. In this regard, the leads are typically attached to pads on the device package by a soldering process.

In aspects, the soldering process may include a solder print, a leadframe placement, and solder reflow. During solder reflow, the leads, which may be part of a leadframe, can be self-aligned to some limited extent due to a surface tension of the molten solder.

However, depending on a design of the pads of the device package, a solder paste volume, a weight of the leads (leadframe), and/or the like, a self-alignment of the leads and the pads can be inconsistent and may result in formation of off-center leads.

In aspects, a more critical lead may be a center lead. In aspects, the center lead may be a thinner or narrower lead in comparison to other leads. In aspects, the center lead may have to be narrower than other leads for impedance matching in RF devices.

Formation of off-center leads may result in a faulty device package, which cannot be utilized, tested, and/or the like. For example, a faulty device package cannot be tested in production, cannot be shipped to customers, and/or the like.

The disclosed device and process makes lead placement more consistent. In aspects, metal pads of the device package can be designed and configured in a way to improve a self-alignment functionality of the leads to the pads.

In particular, the disclosed device and process may utilize a solder mask on the pad of the device package configured in a way to improve a self-alignment functionality of the leads to the pads. More specifically, a width “w” of the solder mask on the pad may be configured in a way to improve a self-alignment functionality of the leads to the pads.

In this regard, it has been found that the wider the pad, the more chance of misalignment with the lead due to more freedom of movement between the lead and the pad. Accordingly, the disclosed device and process may implement a width “w” of the solder mask on the pad that may be configured in a way to improve a self-alignment functionality of the leads to the pads.

However, a device package implementing multiple leads and respective pads need not implement the disclosed solder mask for all of the multiple pads. In aspects, a single implementation of the disclosed solder mask on a single pad may be sufficient, a pair of implementations of the disclosed solder mask on a pair of pads may be sufficient, and/or more than two implementations of the disclosed solder mask on more than two of the pads may be sufficient. However, the disclosed solder mask may be implemented on all of the pads.

In specific examples, an “effective” width of the pad may be formed by the solder mask for soldering. The effective width of the solder mask on the pad may be configured in a way to improve a self-alignment functionality of the leads to the pads. In particular, implementing the solder mask with an appropriate effective width improves alignment of the lead to the pad.

On the other hand, implementing a larger pad and/or implementing a larger pad with a larger effective width of the solder mask provides more misalignment opportunities for the lead.

A narrower pad and/or a narrower “effective” width of the pad defined by the solder mask can also provide benefits to any solder print offset. In this regard, when the solder paste is printed off-center and placed on the solder mask, the solder can be pulled back to the exposed metal portion of the pad during reflow resulting in an improvement to centering the lead.

On the other hand, if the pad is larger, then the solder may just melt in that location. Accordingly, the lead may not be pulled back to the pad, which results in making the lead off-center.

In aspects, the width “w” dimension of the pad and/or the effective width “w” dimension of the pad implemented by the solder mask as disclosed herein should be slightly wider than a lead width. In aspects, the pad for the center lead may not implement the disclosed dimension configurations and/or the solder mask.

In aspects, the width “w” dimension of the pad and/or the effective width “w” dimension of the pad implemented by the solder mask may be calculated as follows:

w=lead width+x, where the “x” dimension may be˜2 mil or smaller than ˜5 mil (max).

As noted above, the pad for the center lead may not implement the disclosed dimension configurations and/or the solder mask. In this regard, the center lead width may be determined by RF designers for impedance matching. For example, impedance matching to 50 ohm, 35 ohm, and/or the like.

Aspects of the disclosed device and process may be implemented in device packages with multiple leads and/or multiple lead products. For example, in device packages where leads are attached to the package by a heating process like soldering, brazing, and/or the like.

Aspects of the disclosed device and process may be implemented in device packages having, for example two, three, four, five, six, seven, eight, nine, and/or n leads in RF devices, semiconductor devices, and/or the like.

For example, the disclosed device and process may be implemented in device packages to provide the disclosed solder mask opening and solder volume on two inner pads, two outer ground pads, and/or the like. In this regard, implementation of the disclosed device and process may bring all leads to center on the pads and provide for self-alignment of the leads.

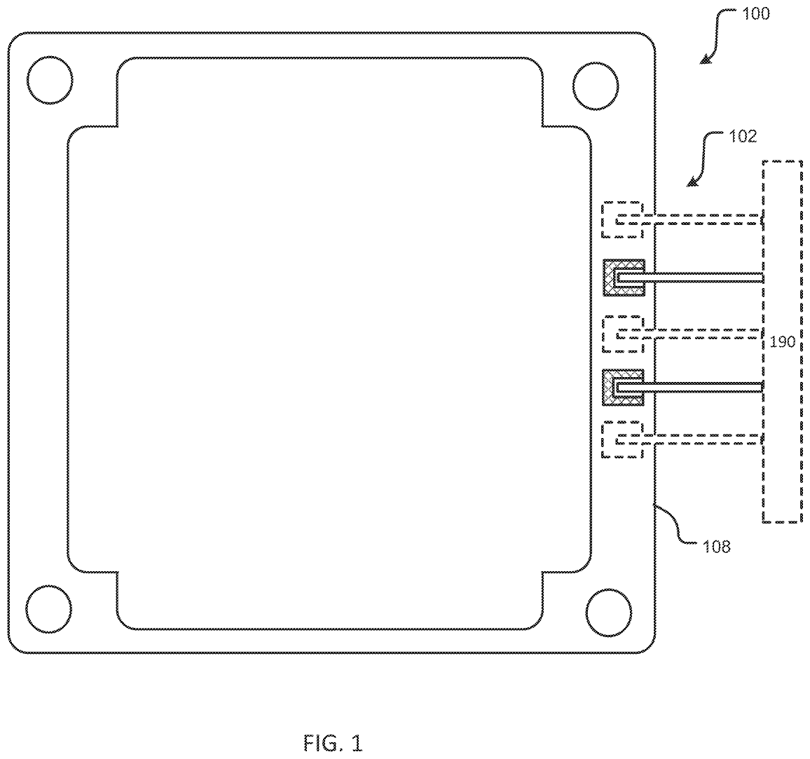

FIG. 1 illustrates a device package according to aspects of the disclosure.

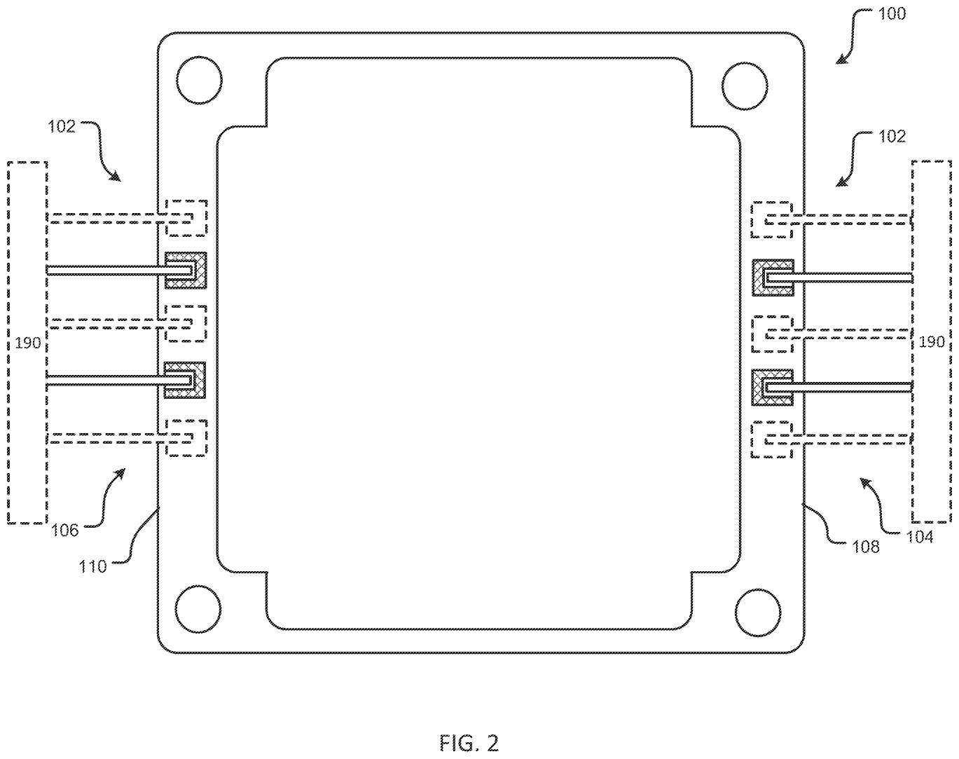

FIG. 2 illustrates another device package according to aspects of the disclosure.

In particular, FIG. 1 illustrates a device package 100 having leads 102 arranged along a first device side 108 of the device package 100. The leads 102 may be configured as one or more signal leads, one or more input signal leads, one or more output signal leads, one or more power leads, one or more ground leads, and/or the like. As shown in FIG. 1, there are two implementations of the leads 102. However, there may be any number of the leads 102 as implied by the dashed lines.

Additionally, one or more of the leads 102 of the device package 100 may be configured with a lead alignment construction. Further, some of the leads 102 may be connected as part of a leadframe 190 during manufacturing of the device package 100. Accordingly, the lead alignment construction of one or more of the leads 102 may provide alignment of all of the leads 102 attached to the leadframe 190. In other words, the leadframe 190 may align connected implementations of the leads 102 when at least one of the leads 102 includes the lead alignment construction.

In aspects, the features and aspects of the device package 100 and/or the leads 102 illustrated in FIG. 1 and described therewith may optionally include any other features or aspects of the device package 100 and/or the leads 102 illustrated in other figures and described herein. Moreover, features and aspects of the device package 100 and/or the leads 102 illustrated in FIG. 1 and described therewith may optionally be included in any other aspects of the device package 100 and/or the leads 102 illustrated in other figures and described herein.

FIG. 2 also illustrates the device package 100 implementing the leads 102 along the first device side 108 of the device package 100. Further, FIG. 2 illustrates implementations of the leads 102 along a second device side 110 of the device package 100.

Here again, one or more of the leads 102 of the device package 100 may be configured with a lead alignment construction. Further, some of the leads 102 may be connected as part of a leadframe 190 during manufacturing of the device package 100. Accordingly, the lead alignment construction of one or more of the leads 102 may provide alignment of all of the leads 102 attached to the leadframe 190. In other words, the leadframe 190 aligns are connected implementations of the leads 102 when at least one of the leads 102 includes the lead alignment construction. In this regard, the leadframe 190 implemented on the second device side 110 may align the leads 102 on the second device side 110; and the leadframe 190 implemented on the first device side 108 may align the leads 102 on the first device side 108. In other aspects, a single implementation of the leadframe 190 may be utilized to form and align the leads 102 on the first device side 108 and the second device side 110.

In aspects, some of the leads 102 may be output signal leads 104. In particular, one or more implementations of the leads 102 on the first device side 108 may be the output signal leads 104.

In aspects, some of the leads 102 may be input signal leads 106. In particular, one or more implementations of the leads 102 on the second device side 110 may be the input signal leads 106.

As shown in FIG. 2, there are two implementations of the leads 102 that may be implemented as the input signal leads 106; and there are two implementations of the leads 102 that may be implemented as the output signal leads 104. However, there may be any number of the input signal leads 106; and there may be any number of the output signal leads 104 as implied by the dashed lines.

Further, some of the input signal leads 106 may be arranged on the first device side 108 and some of the output signal leads 104 may be arranged on the first device side 108 (not shown). Additionally, some of the input signal leads 106 may be arranged on the second device side 110 and some of the output signal leads 104 may be arranged on the second device side 110 (not shown). Moreover, all of the input signal leads 106 may be arranged on the first device side 108 and all of the output signal leads 104 may be arranged on the first device side 108 (not shown). Additionally, all of the input signal leads 106 may be arranged on the second device side 110 and all of the output signal leads 104 may be arranged on the second device side 110 (not shown).

In aspects, the features and aspects of the device package 100 and/or the leads 102 illustrated in FIG. 2 and described therewith may optionally include any other features or aspects of the device package 100 and/or the leads 102 illustrated in other figures and described herein. Moreover, features and aspects of the device package 100 and/or the leads 102 illustrated in FIG. 2 and described therewith may optionally be included in any other aspects of the device package 100 and/or the leads 102 illustrated in other figures and described herein.

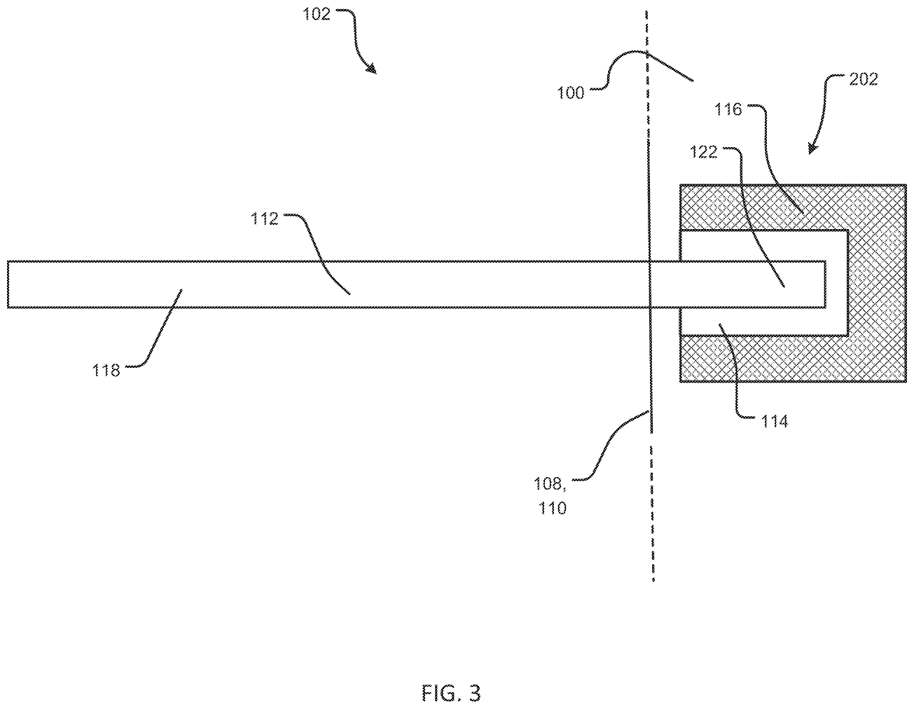

FIG. 3 illustrates partial details of the device package and one of the leads implementing a lead alignment construction according to FIG. 1 and/or FIG. 2.

In particular, FIG. 3 illustrates one of the leads 102 of the device package 100 that may be arranged on the first device side 108 or the second device side 110. One or more of the leads 102 may include a lead structure 112 and an attachment pad 114. Both of the lead structure 112 and the attachment pad 114 may include metal.

Additionally, the lead structure 112 may include an attachment end 122 arranged on the attachment pad 114. Further, the lead structure 112 may include a connection portion 118 to connect the lead structure 112 to another component. In aspects, the leads 102 may include multiple implementations of the lead structure 112, the attachment end 122, and the connection portion 118 that may initially be attached to the leadframe 190 during attachment of the leads 102 to the attachment pad 114. In this regard, once the lead structure 112 and/or the attachment end 122 has been soldered to the attachment pad 114, each implementation of the lead structure 112 may be separated from the leadframe 190 such that the connection portion 118 may be utilized.

The connection portion 118 may extend from the first device side 108 and/or the second device side 110 of the device package 100 away from the attachment pad 114. Further, the attachment pad 114 may be arranged on the device package 100 adjacent the first device side 108 and/or the second device side 110.

Further, the attachment pad 114 of FIG. 3 is shown as being implemented with a lead alignment construction 202. In this regard, the attachment pad 114 may include a solder mask material 116. The solder mask material 116 may be arranged on the attachment pad 114 and at least partially surround an exposed metal area of the attachment pad 114 adjacent the attachment end 122 of the lead structure 112. In particular, the solder mask material 116 may be configured with an arrangement to improve an alignment of the lead structure 112 to the attachment pad 114.

In aspects, the arrangement of the solder mask material 116 may promote alignment of the leads 102, the lead structure 112, and/or the attachment end 122 during solder reflow. In this regard, a solder paste may be arranged on the attachment pad 114 and/or the attachment end 122. Accordingly, when the solder paste is heated during solder reflow, a resulting molten solder will exhibit a surface tension on the attachment end 122. This surface tension of the molten solder may promote movement of the attachment end 122 and accordingly the lead structure 112 on the attachment pad 114. In particular, promote movement of the attachment end 122 toward a center of the attachment pad 114 between the solder mask material 116.

Further, the solder mask material 116 may be configured with dimensions to improve an alignment of the lead structure 112 to the attachment pad 114. In aspects, the dimensions of the solder mask material 116 may promote alignment of the leads 102, the lead structure 112, and/or the attachment end 122 during solder reflow based on the molten solder exhibiting a surface tension on the attachment end 122.

Additionally, the attachment pad 114 may be configured with dimensions to improve an alignment of the lead structure 112. In aspects, the dimensions of the attachment pad 114 may promote alignment of the leads 102, the lead structure 112, and/or the attachment end 122 during solder reflow based on the molten solder exhibiting a surface tension on the attachment end 122.

In aspects, the solder mask material 116 may be a solder mask, a solder stopper, a solder resist and/or the like. In aspects, the solder mask material 116 may be an epoxy, an ultraviolet curable material, an ultraviolet curable epoxy, a layer of polymer, photoimageable solder mask (LPSM or LPI) inks, a dry-film photoimageable solder mask (DFSM), and/or the like. In aspects, the solder mask material 116 may be applied by a dispenser, silkscreen application, and/or the like.

In aspects, the lead structure 112 may be formed of any metal material including gold, copper, aluminum, and/or the like. In aspects, the attachment pad 114 may be formed of any metal material including gold, copper, aluminum, and/or the like.

In aspects, the features and aspects of the device package 100 and/or the leads 102 illustrated in FIG. 3 and described therewith may optionally include any other features or aspects of the device package 100 and/or the leads 102 illustrated in other figures and described herein. Moreover, features and aspects of the device package 100 and/or the leads 102 illustrated in FIG. 3 and described therewith may optionally be included in any other aspects of the device package 100 and/or the leads 102 illustrated in other figures and described herein.

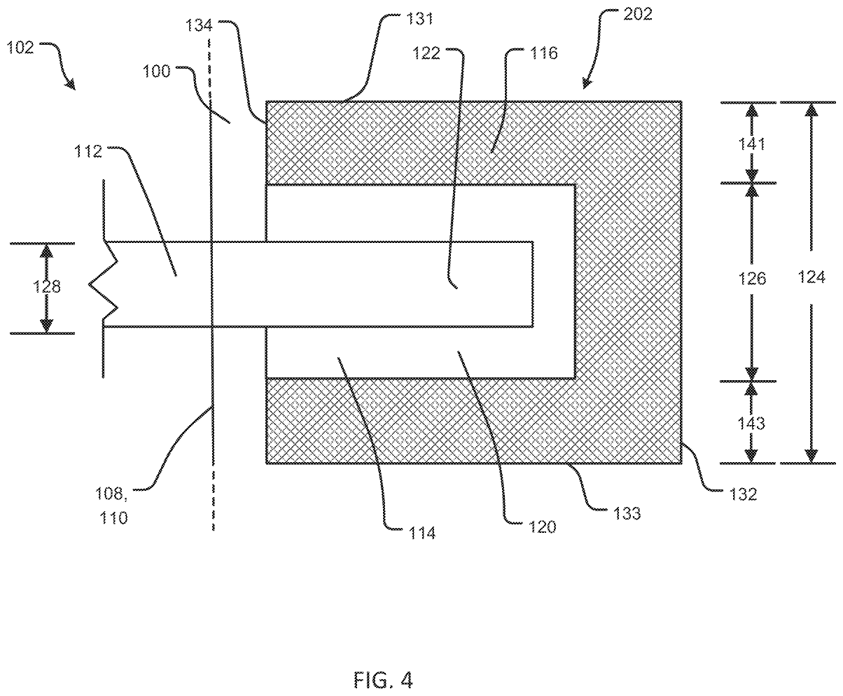

FIG. 4 illustrates further details of one of the leads having the lead alignment construction according to FIG. 3.

As illustrated in FIG. 4, the solder mask material 116 may be arranged on a surface of the attachment pad 114. In particular, the solder mask material 116 may arranged along one side, two sides, three sides, and/or the like of the attachment pad 114. As illustrated in FIG. 4, the solder mask material 116 may arranged along three sides of the attachment pad 114. Additionally, the solder mask material 116 may be arranged such that there is an attachment area 120. In aspects, the attachment area 120 may be an exposed metal area of the attachment pad 114. In aspects, the attachment area 120 may be configured to receive solder for attachment of the lead structure 112 to the attachment pad 114 and/or the attachment area 120. In aspects, the solder may be arranged on the attachment pad 114 and/or the attachment end 122 as a solder paste, which may be applied by a solder paste dispenser, a solder paste stencil application device, and/or the like.

More specifically, the attachment pad 114 may include a first pad side 131, a second pad side 132, a third pad side 133, and a fourth pad side 134. In aspects, the first pad side 131 may be connected to the second pad side 132 at a corner of the attachment pad 114. In aspects, the second pad side 132 may be connected to the third pad side 133 at a corner of the attachment pad 114. In aspects, the third pad side 133 may be connected to the fourth pad side 134 at a corner of the attachment pad 114.

In aspects, the fourth pad side 134 may be connected to the first pad side 131 at a corner of the attachment pad 114. In this regard, the fourth pad side 134 may be arranged adjacent the first device side 108 and/or the second device side 110. Further, the lead structure 112 may extend toward the device package 100 past the first device side 108 and/or the second device side 110; and the lead structure 112 may extend past the fourth pad side 134 of the attachment pad 114 such that the attachment end 122 is positioned within the attachment area 120.

In aspects, the solder mask material 116 may be arranged adjacent the first pad side 131 and extend from the fourth pad side 134 to the second pad side 132 of the attachment pad 114. In this aspect, this arrangement of the solder mask material 116 may form a first portion of the solder mask material 116.

Additionally, the solder mask material 116 may extend from the first pad side 131 to the third pad side 133 adjacent the second pad side 132. In this aspect, this arrangement of the solder mask material 116 may form a second portion of the solder mask material 116.

Further, the solder mask material 116 may extend from the second pad side 132 to the first pad side 131 adjacent the third pad side 133. In this aspect, this arrangement of the solder mask material 116 may form a third portion of the solder mask material 116.

In aspects, an arrangement and/or dimensions of the first portion of the solder mask material 116, the second portion of the solder mask material 116, and the third portion of the solder mask material 116 may promote alignment of the leads 102, the lead structure 112, and/or the attachment end 122 during solder reflow based on the molten solder exhibiting a surface tension on the attachment end 122.

In aspects, this arrangement of the solder mask material 116 may form the attachment area 120 on the attachment pad 114. The attachment area 120 may be an area on the attachment pad 114 without any of the solder mask material 116 arranged therein. In aspects, the attachment area 120 may be surrounded on three sides by the solder mask material 116.

The attachment pad 114 may have a pad width 124 as illustrated in FIG. 4. In this regard, the pad width 124 may be a distance from the first pad side 131 to the third pad side 133. In aspects, the pad width 124 may promote alignment of the leads 102, the lead structure 112, and/or the attachment end 122 during solder reflow.

Further, the attachment area 120 may have an attach width 126 as illustrated in FIG. 4. The attach width 126 of the attachment area 120 may be the exposed metal area between the second pad side 132 and the fourth pad side 134 without the solder mask material 116. In aspects, the attach width 126 may be in area between the first portion of the solder mask material 116 and the third portion of the solder mask material 116.

In aspects, the dimensions of the attach width 126 may promote alignment of the leads 102, the lead structure 112, and/or the attachment end 122 during solder reflow based on the molten solder exhibiting a surface tension on the attachment end 122.

Additionally, the solder mask material 116 may have a first mask portion width 141; and the solder mask material 116 may have a third mask portion width 143. In this regard, the sum of the first mask portion width 141, the attach width 126, and the third mask portion width 143 may be generally equal to the pad width 124.

In aspects, the dimensions of the first mask portion width 141 and the third mask portion width 143 may promote alignment of the leads 102, the lead structure 112, and/or the attachment end 122 during solder reflow based on the molten solder exhibiting a surface tension on the attachment end 122.

Additionally, the lead structure 112 may have a lead width 128 as illustrated in FIG. 4. In this regard, the pad width 124 may be greater than the attach width 126; and the attach width 126 may be greater than the lead width 128.

In aspects, the features and aspects of the device package 100 and/or the leads 102 illustrated in FIG. 4 and described therewith may optionally include any other features or aspects of the device package 100 and/or the leads 102 illustrated in other figures and described herein. Moreover, features and aspects of the device package 100 and/or the leads 102 illustrated in FIG. 4 and described therewith may optionally be included in any other aspects of the device package 100 and/or the leads 102 illustrated in other figures and described herein.

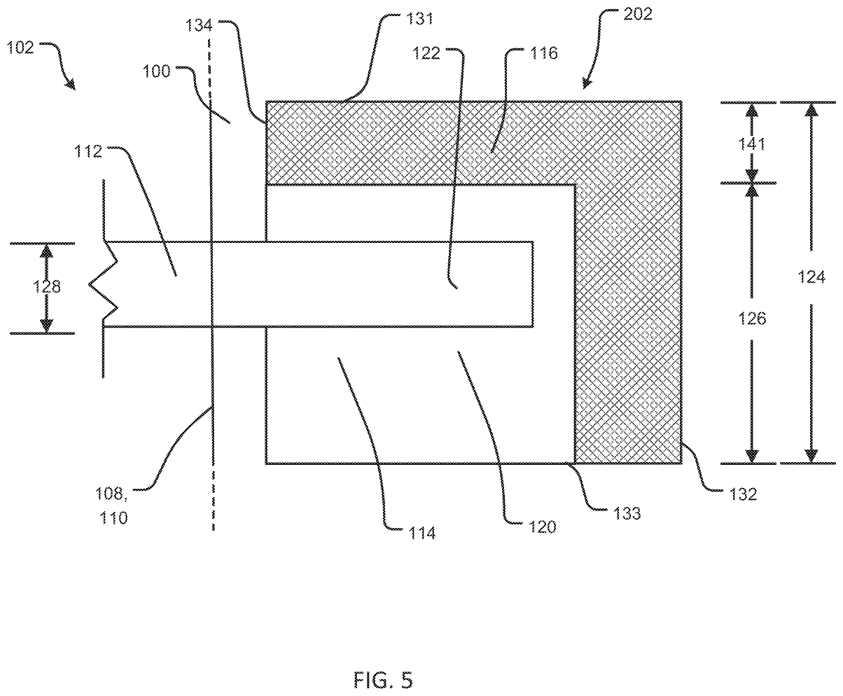

FIG. 5 illustrates another implementation of one of the leads having the lead alignment construction according to aspects of the disclosure.

In aspects, the solder mask material 116 may be arranged adjacent the first pad side 131 and extend from the fourth pad side 134 to the second pad side 132 of the attachment pad 114. In this aspect, this arrangement of the solder mask material 116 may form the first portion of the solder mask material 116.

Additionally, the solder mask material 116 may extend from the first pad side 131 to the third pad side 133 adjacent the second pad side 132. In this aspect, this arrangement of the solder mask material 116 may form the second portion of the solder mask material 116.

Further, the solder mask material 116 may not be present from the second pad side 132 to the first pad side 131 adjacent the third pad side 133. In this aspect, this arrangement of the solder mask material 116 may not include the third portion of the solder mask material 116.

In aspects, an arrangement and/or dimensions of the first portion of the solder mask material 116 and the second portion of the solder mask material 116 may promote alignment of the leads 102, the lead structure 112, and/or the attachment end 122 during solder reflow based on the molten solder exhibiting a surface tension on the attachment end 122.

In aspects, this arrangement of the solder mask material 116 may form the attachment area 120 on the attachment pad 114. The attachment area 120 may be an exposed metal area on the attachment pad 114 without any of the solder mask material 116 arranged therein. In aspects, the attachment area 120 may be surrounded on two sides by the solder mask material 116.

In aspects, dimensions of the attach width 126 may promote alignment of the leads 102, the lead structure 112, and/or the attachment end 122 during solder reflow based on the molten solder exhibiting a surface tension on the attachment end 122.

In aspects, the features and aspects of the device package 100 and/or the leads 102 illustrated in FIG. 5 and described therewith may optionally include any other features or aspects of the device package 100 and/or the leads 102 illustrated in other figures and described herein. Moreover, features and aspects of the device package 100 and/or the leads 102 illustrated in FIG. 5 and described therewith may optionally be included in any other aspects of the device package 100 and/or the leads 102 illustrated in other figures and described herein.

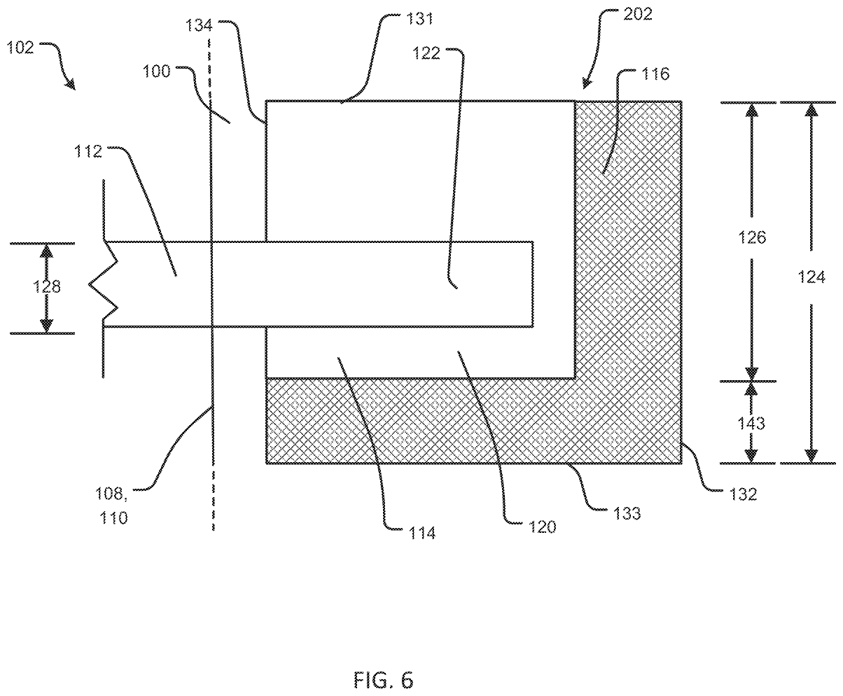

FIG. 6 illustrates another implementation of one of the leads having the lead alignment construction according to aspects of the disclosure.

In aspects, the solder mask material 116 may extend from the first pad side 131 to the third pad side 133 adjacent the second pad side 132. In this aspect, this arrangement of the solder mask material 116 may form the second portion of the solder mask material 116.

Additionally, the solder mask material 116 may extend from the second pad side 132 to the first pad side 131 adjacent the third pad side 133. In this aspect, this arrangement of the solder mask material 116 may form the third portion of the solder mask material 116.

In aspects, the solder mask material 116 may not be arranged adjacent the first pad side 131 and may not extend from the fourth pad side 134 to the second pad side 132 of the attachment pad 114. In this aspect, this arrangement of the solder mask material 116 may not include the first portion of the solder mask material 116.

In aspects, an arrangement and/or dimensions of the second portion of the solder mask material 116 and the third portion of the solder mask material 116 may promote alignment of the leads 102, the lead structure 112, and/or the attachment end 122 during solder reflow based on the molten solder exhibiting a surface tension on the attachment end 122.

In aspects, this arrangement of the solder mask material 116 may form the attachment area 120 on the attachment pad 114. The attachment area 120 may be an area on the attachment pad 114 without any of the solder mask material 116 arranged therein. In aspects, the attachment area 120 may be surrounded on two sides by the solder mask material 116.

In aspects, dimensions of the attach width 126 may promote alignment of the leads 102, the lead structure 112, and/or the attachment end 122 during solder reflow based on the molten solder exhibiting a surface tension on the attachment end 122.

In aspects, the features and aspects of the device package 100 and/or the leads 102 illustrated in FIG. 6 and described therewith may optionally include any other features or aspects of the device package 100 and/or the leads 102 illustrated in other figures and described herein. Moreover, features and aspects of the device package 100 and/or the leads 102 illustrated in FIG. 6 and described therewith may optionally be included in any other aspects of the device package 100 and/or the leads 102 illustrated in other figures and described herein.

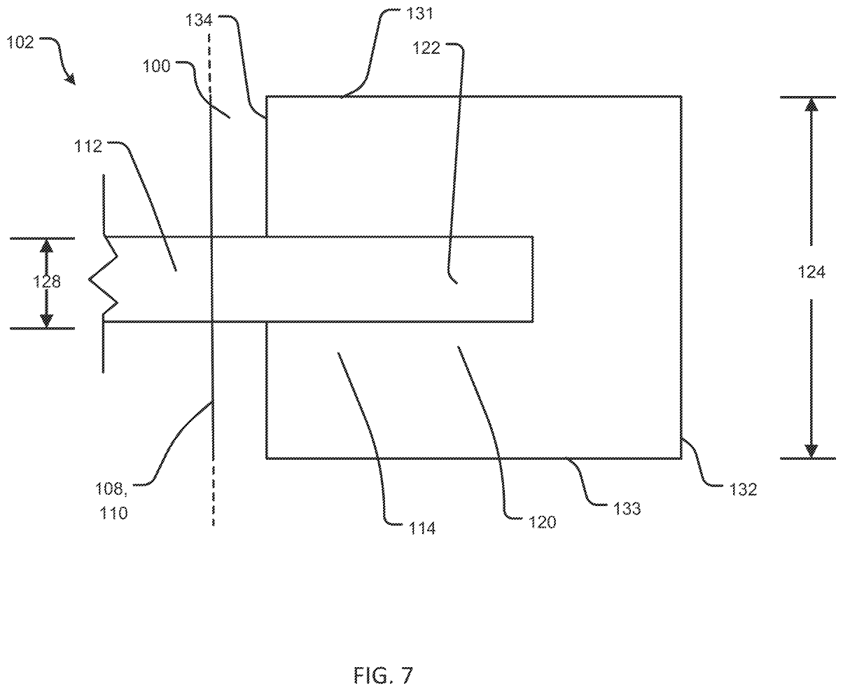

FIG. 7 illustrates partial details of the device package and one of the leads not implementing the lead alignment construction according to FIG. 1 and/or FIG. 2.

In particular, FIG. 7 illustrates partial details of the device package and one of the leads not implementing the lead alignment construction 202 according to FIG. 1 and/or FIG. 2. More specifically, the attachment pad 114 of FIG. 7 is implemented without the solder mask material 116. In aspects, the remaining features of the leads 102 illustrated in FIG. 7 may be generally consistent with a construction of the leads 102 illustrated in FIG. 3 and FIG. 4.

In aspects, the features and aspects of the device package 100 and/or the leads 102 illustrated in FIG. 7 and described therewith may optionally include any other features or aspects of the device package 100 and/or the leads 102 illustrated in other figures and described herein. Moreover, features and aspects of the device package 100 and/or the leads 102 illustrated in FIG. 7 and described therewith may optionally be included in any other aspects of the device package 100 and/or the leads 102 illustrated in other figures and described herein.

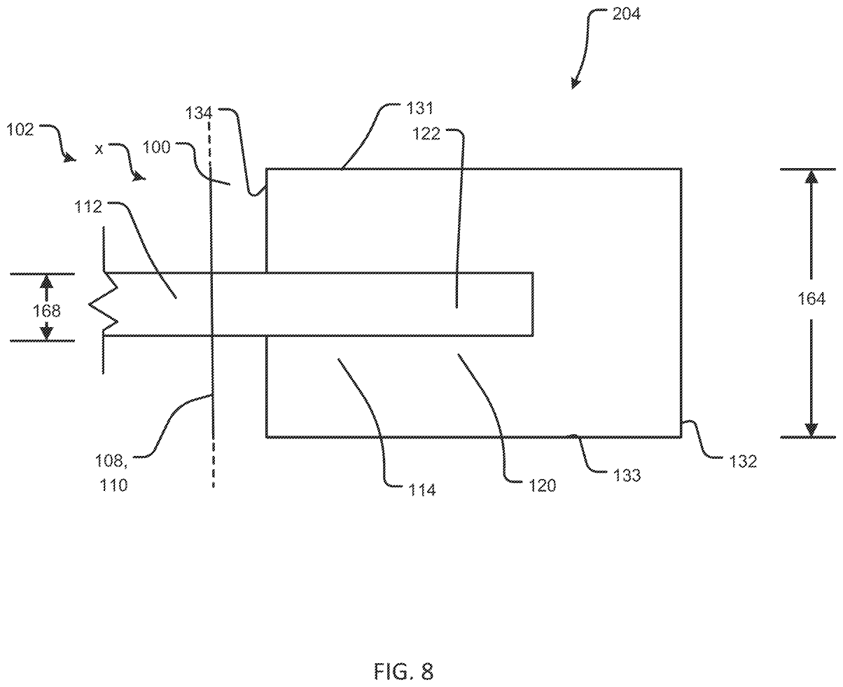

FIG. 8 illustrates partial details of the device package and one of the leads not implementing the lead alignment construction according to FIG. 1 and/or FIG. 2.

In particular, FIG. 8 illustrates partial details of the device package and one of the leads not implementing the lead alignment construction 202 according to FIG. 1 and/or FIG. 2. More specifically, the attachment pad 114 of FIG. 8 is implemented without the solder mask material 116.

In aspects, the lead structure 112 and/or the attachment pad 114 illustrated in FIG. 8 may be a narrow lead implementation 204. In aspects, the narrow lead implementation 204 may be a narrower implementation of the lead structure 112. In aspects, the narrow lead implementation 204 may be a narrower implementation of the attachment pad 114. In aspects, the narrow lead implementation 204 may be a narrower implementation of the lead structure 112 and a narrower implementation of the attachment pad 114.

In aspects, the lead structure 112 may have a lead width 168 as illustrated in FIG. 8. In aspects, the attachment pad 114 may have a pad width 164 as illustrated in FIG. 8. In this regard, the pad width 124 may be a distance from the first pad side 131 to the third pad side 133.

In aspects, the lead width 168 of the lead structure 112 in FIG. 8 may be less than the lead width 128 of the lead structure 112 illustrated in FIG. 4. In aspects, the pad width 164 of the attachment pad 114 in FIG. 8 may be less than the pad width 124 of the attachment pad 114 illustrated in FIG. 4.

In aspects, the remaining features of the leads 102 illustrated in FIG. 8 may be generally consistent with a construction of the leads 102 illustrated in FIG. 3 and FIG. 4.

In aspects, the features and aspects of the device package 100 and/or the leads 102 illustrated in FIG. 8 and described therewith may optionally include any other features or aspects of the device package 100 and/or the leads 102 illustrated in other figures and described herein. Moreover, features and aspects of the device package 100 and/or the leads 102 illustrated in FIG. 8 and described therewith may optionally be included in any other aspects of the device package 100 and/or the leads 102 illustrated in other figures and described herein.

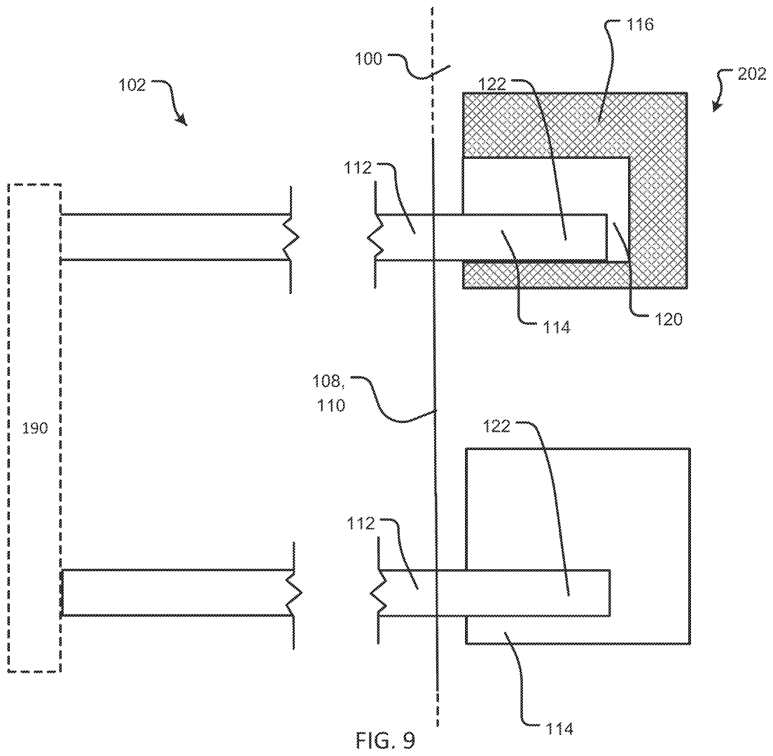

FIG. 9 illustrates partial details of the device package prior to solder reflow according to aspects of the disclosure.

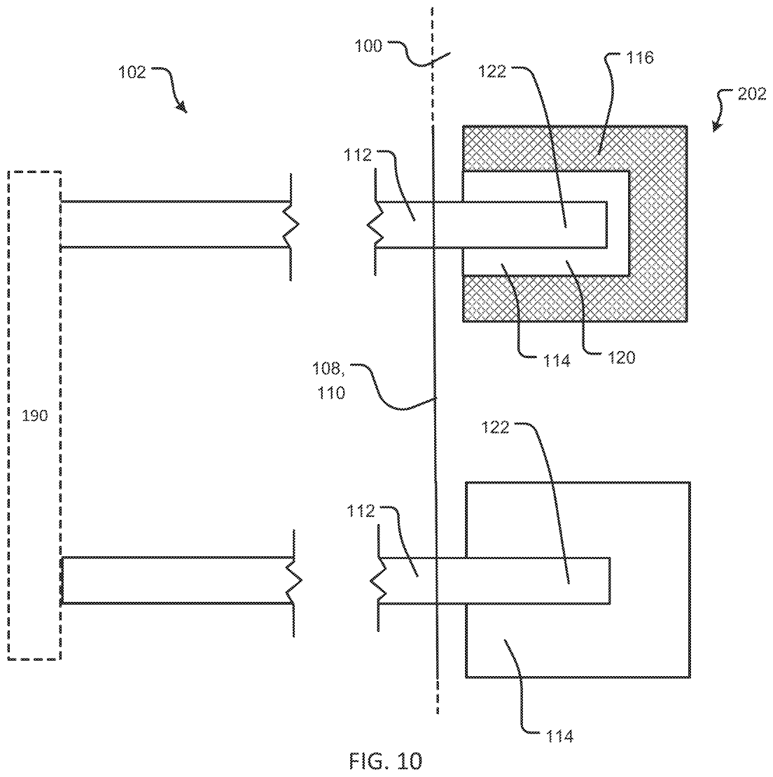

FIG. 10 illustrates partial details of the device package after solder reflow according to FIG. 9.

In particular, FIG. 9 illustrates the device package 100 implementing one of the leads 102 implementing the lead alignment construction 202, and one of the leads 102 not implementing the lead alignment construction 202 prior to solder reflow. Other possible implementations of the leads 102 are not shown for ease of illustration.

In this regard, FIG. 9 illustrates that the implementations of the lead structure 112 are connected to the leadframe 190. Further, the location of respective implementations of the attachment end 122 are off-center on the respective implementations of the attachment pad 114. Although the device package 100 illustrated in FIG. 9 shows two implementations of the leads 102, the device package 100 may implement any number of the leads 102 as described herein.

FIG. 10 illustrates the device package 100 implementing one of the leads 102 implementing the lead alignment construction 202, and one of the leads 102 not implementing the lead alignment construction 202 after solder reflow. In this regard, implementation of the lead alignment construction 202 has been utilized to promote the solder to move the attachment end 122 with the lead alignment construction 202 to be centered as described herein. Further, because the implementations of the leads 102 are connected through the leadframe 190, the implementation of the leads 102 without the lead alignment construction 202 is likewise moved and accordingly centered on the attachment pad 114.

In aspects, the device package 100 having multiple implementations of the lead structure 112 and multiple respective implementations of the attachment pad 114 need not implement the solder mask material 116 and/or the lead alignment construction 202 for all of the multiple implementations of the attachment pad 114. In aspects, a single implementation of the solder mask material 116 on a single implementation of the attachment pad 114 may be sufficient, a pair of implementations of the solder mask material 116 on a pair of the attachment pad 114 may be sufficient, and/or more than two implementations of the attachment pad 114 on more than two implementations of the attachment pad 114 may be sufficient. However, the solder mask material 116 may be implemented on all implementations of the attachment pad 114.

In aspects, an “effective” width of the attachment pad 114 may be formed by the solder mask material 116 for soldering. In aspects, the effective width may be the attach width 126 as described herein. The effective width of the solder mask material 116 on the attachment pad 114 may be configured in a way to improve a self-alignment functionality of the leads 102 and/or the lead structure 112 to the attachment pad 114. In particular, implementing the solder mask material 116 with an appropriate effective width may improve alignment of the leads 102 and/or the lead structure 112 to the attachment pad 114. More specifically, implementing the solder mask material 116 with an appropriate effective width as defined by the attach width 126 may improve alignment of the leads 102 and/or the lead structure 112 to the attachment pad 114.

In aspects, an “effective” width of the attachment pad 114 may be the attach width 126 as described herein. The effective width of the attachment pad 114 may be configured in a way to improve a self-alignment functionality of the leads 102 and/or the lead structure 112 to the attachment pad 114. In particular, implementing the effective width may improve alignment of the leads 102 and/or the lead structure 112 to the attachment pad 114.

In aspects an implementation of the attachment pad 114 and/or a narrower “effective” width of the attachment pad 114 defined by the solder mask material 116 can also provide benefits to any solder print offset. In this regard, when the solder paste is printed off-center and placed on the solder mask material 116, the solder can be pull back the lead structure 112 and/or the attachment end 122 to the exposed metal portion of the attachment pad 114, such as the attachment area 120 during reflow resulting in an improvement to centering the leads 102 and/or the lead structure 112.

In aspects, the width “w” dimension of the attachment pad 114 and/or the effective width “w” dimension of the attachment pad 114 implemented by the solder mask material 116 as disclosed herein should be slightly wider than a lead width. In this regard, the width “w” dimension of the attachment pad 114 may be defined by the pad width 124 as illustrated and described herein; the effective width “w” dimension of the attachment pad 114 implemented by the solder mask material 116 may be defined by the attach width 126 as illustrated and described herein; and a lead width may be defined by the lead width 128 as illustrated and described herein.

In aspects, the attachment pad 114 for a center implementation of the leads 102 and/or the lead structure 112 may not implement the disclosed dimension configurations and/or the solder mask material 116.

In aspects, the width “w” dimension of the attachment pad 114 and/or the effective width “w” dimension of the attachment pad 114 implemented by the solder mask material 116 may be calculated as follows:

$$w = lead width + x .$$

In aspects, the “x” dimension may be more than 1 mil, 2 mil, 3 mil, 4 mil, or 5 mil. In aspects, the “x” dimension may be less than 2 mil, 3 mil, 4 mil, 5 mil, or 6 mil (max). In aspects, the “x” dimension may be ˜2 mil or smaller than ˜5 mil (max).

In aspects, the “x” dimension may be a function of the lead width 128. In aspects, the “x” dimension may be 10%, 20%, 30%, 40%, 50%, 60%, 70%, or 80% greater than the lead width 128. In aspects, the “x” dimension may be 20%, 30%, 40%, 50%, 60%, 70%, or 80% less than the lead width 128. In aspects, the “x” dimension may be 10%-20%, 20%-30%, 30%-40%, 40%-50%, 50%-60%, 60%-70%, or 70%-80% of the lead width 128.

In aspects, the width “w” may be the attach width 126 as illustrated and described herein; and the lead width may be the lead width 128 as illustrated and described herein.

As noted above, the attachment pad 114 for the center implementation of the lead structure 112 may not implement the disclosed dimension configurations and/or the solder mask material 116. In this regard, the center lead width may be determined by RF designers for impedance matching. For example, impedance matching to 50 ohm, 35 ohm, and/or the like.

Aspects of the disclosure may be implemented in device packages with multiple leads and/or multiple lead products. For example, in device packages where leads are attached to the package by a heating process like soldering, brazing, and/or the like.

Aspects of the device package 100 may have two, three, four, five, six, seven, eight, nine, and/or n implementations of the leads 102 leads in RF devices, semiconductor devices, and/or the like.

For example, the disclosed implementations of the solder mask material 116 and/or the lead alignment construction 202 may be implemented in device packages to provide the disclosed solder mask opening and solder volume on two inner implementations of the attachment pad 114, two outer implementations of the attachment pad 114, and/or the like. In this regard, implementation of the disclosed implementation of the solder mask material 116 and/or the lead alignment construction 202 may bring all implementations of the leads 102 to center on the attachment pad 114 and provide for self-alignment of the leads 102.

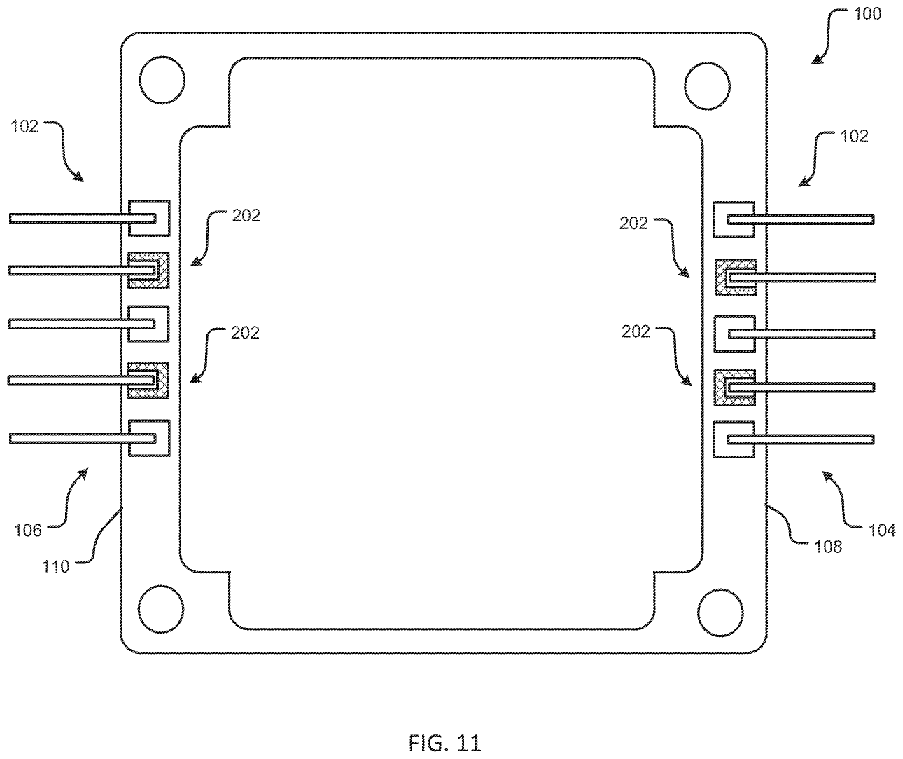

FIG. 11 illustrates another device package according to aspects of the disclosure.

As illustrated in FIG. 11, the device package 100 may implement any number of the leads 102 with the lead alignment construction 202. Further, the device package 100 may implement any number of the leads 102 without the lead alignment construction 202. Moreover, the device package 100 may implement any arrangement of the leads 102 with the lead alignment construction 202; and the device package 100 may implement any arrangement of the leads 102 without the lead alignment construction 202.

As illustrated in FIG. 11, an exemplary implementation of the device package 100 is shown implementing five of the leads 102 on the second device side 110; and five of the leads 102 on the first device side 108. Further, FIG. 11 illustrates that two inner implementations of the leads 102 on the second device side 110 are implemented with the lead alignment construction 202; and two inner implementations of the leads 102 on the first device side 108 are implemented with the lead alignment construction 202.

In aspects, the features and aspects of the device package 100 and/or the leads 102 illustrated in FIG. 11 and described therewith may optionally include any other features or aspects of the device package 100 and/or the leads 102 illustrated in other figures and described herein. Moreover, features and aspects of the device package 100 and/or the leads 102 illustrated in FIG. 11 and described therewith may optionally be included in any other aspects of the device package 100 and/or the leads 102 illustrated in other figures and described herein.

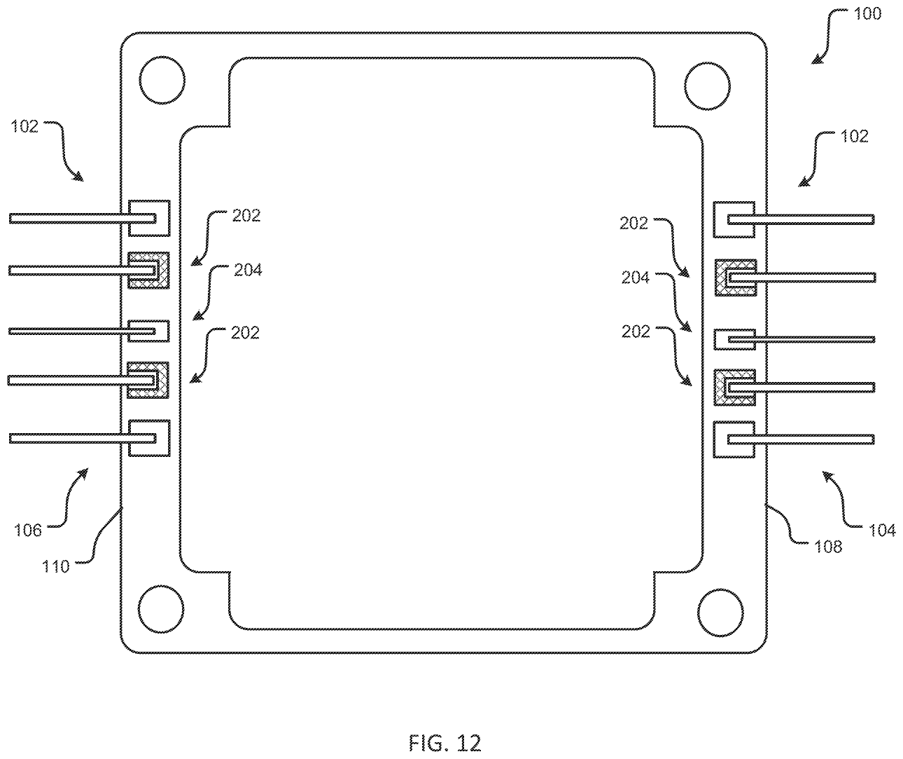

FIG. 12 illustrates another device package according to aspects of the disclosure.

As illustrated in FIG. 12, the device package 100 may implement any number of the leads 102 with the lead alignment construction 202. Further, the device package 100 may implement any number of the leads 102 without the lead alignment construction 202. Additionally, the device package 100 may implement any number of the leads 102 without the narrow lead implementation 204.

Moreover, the device package 100 may implement any arrangement of the leads 102 with the lead alignment construction 202; the device package 100 may implement any arrangement of the leads 102 without the lead alignment construction 202; and the device package 100 may implement any arrangement of the leads 102 with the narrow lead implementation 204.

As illustrated in FIG. 12, an exemplary implementation of the device package 100 is shown implementing five of the leads 102 on the second device side 110; and five of the leads 102 on the first device side 108. Further, FIG. 12 illustrates that two inner implementations of the leads 102 on the second device side 110 are implemented with the lead alignment construction 202; and two inner implementations of the leads 102 on the first device side 108 are implemented with the lead alignment construction 202.

Additionally, FIG. 12 illustrates that a center implementation of the leads 102 on the second device side 110 is implemented with the narrow lead implementation 204; and a center implementation of the leads 102 on the first device side 108 is implemented with the narrow lead implementation 204.

In aspects, the features and aspects of the device package 100 and/or the leads 102 illustrated in FIG. 12 and described therewith may optionally include any other features or aspects of the device package 100 and/or the leads 102 illustrated in other figures and described herein. Moreover, features and aspects of the device package 100 and/or the leads 102 illustrated in FIG. 12 and described therewith may optionally be included in any other aspects of the device package 100 and/or the leads 102 illustrated in other figures and described herein.

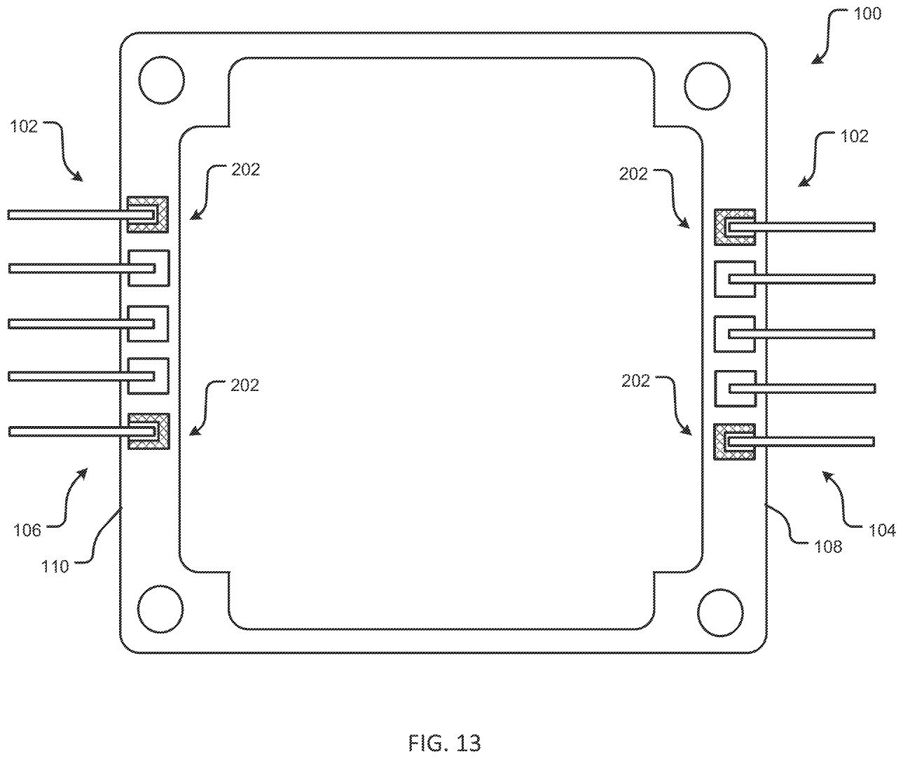

FIG. 13 illustrates another device package according to aspects of the disclosure.

As illustrated in FIG. 13, the device package 100 may implement any number of the leads 102 with the lead alignment construction 202. Further, the device package 100 may implement any number of the leads 102 without the lead alignment construction 202. Moreover, the device package 100 may implement any arrangement of the leads 102 with the lead alignment construction 202; and the device package 100 may implement any arrangement of the leads 102 without the lead alignment construction 202.

As illustrated in FIG. 13, an exemplary implementation of the device package 100 is shown implementing five of the leads 102 on the second device side 110; and five of the leads 102 on the first device side 108. Further, FIG. 13 illustrates that two outer implementations of the leads 102 on the second device side 110 are implemented with the lead alignment construction 202; and two outer implementations of the leads 102 on the first device side 108 are implemented with the lead alignment construction 202.

In aspects, the features and aspects of the device package 100 and/or the leads 102 illustrated in FIG. 13 and described therewith may optionally include any other features or aspects of the device package 100 and/or the leads 102 illustrated in other figures and described herein. Moreover, features and aspects of the device package 100 and/or the leads 102 illustrated in FIG. 13 and described therewith may optionally be included in any other aspects of the device package 100 and/or the leads 102 illustrated in other figures and described herein.

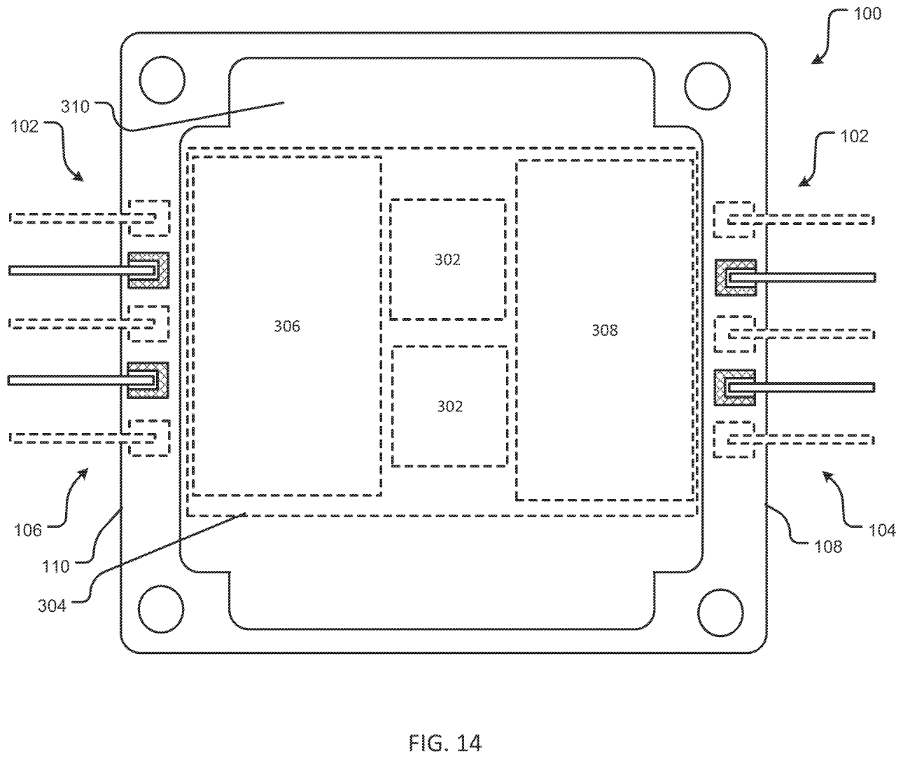

FIG. 14 illustrates another device package according to aspects of the disclosure.

In particular, FIG. 14 illustrates that the device package 100 may be implemented as a RF package, a RF amplifier package, a RF power amplifier package, a RF power transistor package, a RF power amplifier transistor package, and/or the like. As further illustrated in FIG. 14, the device package 100 may include one or more semiconductor devices 302, a support 304, and/or the like. In aspects, the one or more semiconductor devices 302 may be attached to the support 304 via a die attach material. One or more interconnects may couple the one or more semiconductor devices 302 to the leads 102.

In aspects, the device package 100 may include an input network 306. In aspects the input network 306 may include one or more resistors, one or more capacitors, one or more inductors, and/or the like. One or more interconnects may couple the one or more semiconductor devices 302 to the leads 102 and/or the input network 306. One or more interconnects may couple the leads 102 to the input network 306.

In aspects, the device package 100 may include an output network 308. In aspects the output network 308 may include one or more resistors, one or more capacitors, one or more inductors, and/or the like. One or more interconnects may couple the one or more semiconductor devices 302 to the leads 102 and/or the output network 308. One or more interconnects may couple the leads 102 to the output network 308.

The support 304 may dissipate the heat generated by the one or more semiconductor devices 302. In aspects, the die attach material may utilize an adhesive, soldering, sintering, eutectic bonding, thermal compression bonding, ultrasonic bonding/welding, a clip component, and/or the like as described herein. The support 304 may be implemented as a metal submount and may be implemented as a support, a surface, a package support, a package surface, a package support surface, a flange, a metal flange, a heat sink, a common source support, a common source surface, a common source package support, a common source package surface, a common source package support surface, a common source flange, a common source heat sink, a leadframe, a metal leadframe and/or the like. The support 304 may include an insulating material, a dielectric material, and/or the like.

The one or more semiconductor devices 302 may be implemented as one or more of a wide band-gap semiconductor device, an ultra-wideband device, a GaN based device, a Metal Semiconductor Field-Effect Transistor (MESFET), a Metal Oxide Field Effect Transistor (MOSFET), a Junction Field Effect Transistor (JFET), a Bipolar Junction Transistor (BJT), an Insulated Gate Bipolar Transistor (IGBT), a high-electron-mobility transistor (HEMT), a Wide Band Gap (WBG) semiconductor, and/or the like.

In aspects, the device package 100 may be implemented as a General-Purpose Broadband component, a Telecom component, a L-Band component, a S-Band component, a X-Band component, a C-Band component, a Ku-Band component, a Satellite Communications component, a Doherty configuration, and/or the like.

The device package 100 may include a housing 310. In aspects, the housing 310 may be a ceramic body, an over-mold, and/or the like. The housing 310 may substantially surround the one or more semiconductor devices 302, which are mounted on the support 304. The housing 310 may be formed of a plastic or a plastic polymer compound, which may be injection molded around the support 304, the one or more semiconductor devices 302, and/or the like. In this regard, it should be noted that the one or more semiconductor devices 302, the support 304, the input network 306, and the output network 308 are shown with dashed lines as they are within the housing 310 and may not be outwardly visible.

In aspects, the features and aspects of the device package 100 and/or the leads 102 illustrated in FIG. 14 and described therewith may optionally include any other features or aspects of the device package 100 and/or the leads 102 illustrated in other figures and described herein. Moreover, features and aspects of the device package 100 and/or the leads 102 illustrated in FIG. 14 and described therewith may optionally be included in any other aspects of the device package 100 and/or the leads 102 illustrated in other figures and described herein.

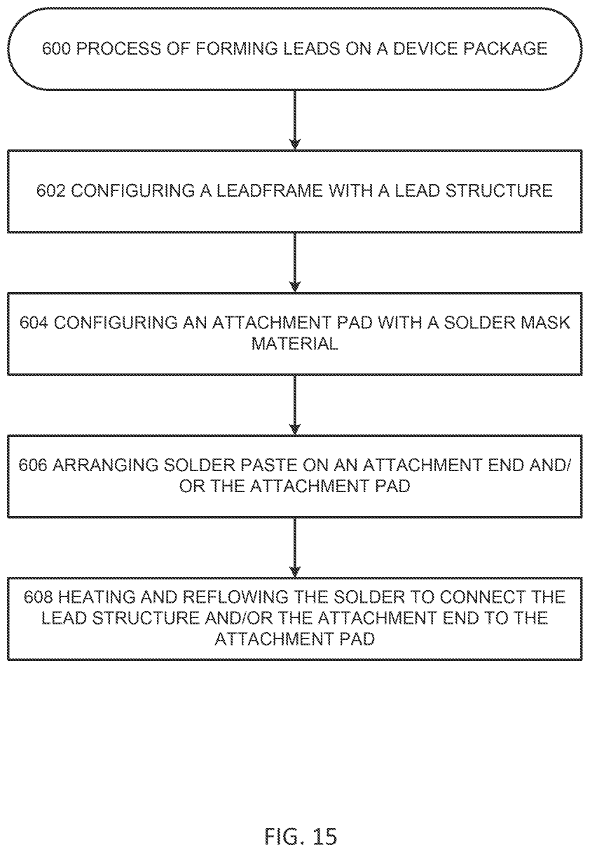

FIG. 15 illustrates an exemplary process of forming leads on a device package according to aspects of the disclosure.

In particular, FIG. 15 illustrates an exemplary process of forming leads on a device package 600. In particular, it should be noted that the process of forming leads on a device package 600 is merely exemplary and may be modified consistent with the various aspects disclosed herein. Moreover, the process of forming leads on a device package 600 of the disclosure may include a process of manufacturing the device package 100. It should be noted that the process of forming leads on a device package 600 may be performed in a different order consistent with the aspects described above. Moreover, the process of forming leads on a device package 600 may be modified to have more or fewer process steps consistent with the various aspects disclosed herein.

The process of forming leads on a device package 600 of the disclosure may include configuring a leadframe with a lead structure 602. In this regard, the configuring a leadframe with a lead structure 602 may include any one or more materials, structures, arrangements, processes, and/or the like as described herein. Moreover, one or more proceeding or subsequent processes may also be implemented with respect to the configuring a leadframe with a lead structure 602 consistent with the disclosure.

In aspects, the configuring a leadframe with a lead structure 602 may include forming the leads 102 on the device package 100 as described herein. In aspects, forming the leads 102 may include forming the lead structure 112, the connection portion 118, and/or the attachment end 122. In aspects, forming the leads 102 may include forming the lead structure 112, the connection portion 118, and/or the attachment end 122 with the lead width 128 and/or the lead width 168.

The process of forming leads on a device package 600 of the disclosure may include configuring an attachment pad with a solder mask material 604. In this regard, the configuring an attachment pad with a solder mask material 604 may include any one or more materials, structures, arrangements, processes, and/or the like as described herein. Moreover, one or more proceeding or subsequent processes may also be implemented with respect to the configuring an attachment pad with a solder mask material 604 consistent with the disclosure.

In aspects, the configuring an attachment pad with a solder mask material 604 may include configuring the attachment pad 114 with the solder mask material 116 as described herein. In aspects, configuring the attachment pad 114 with the solder mask material 116 that may include the first mask portion width 141 and/or the third mask portion width 143.

The process of forming leads on a device package 600 of the disclosure may include arranging solder paste on an attachment end and/or the attachment pad 606. In this regard, the arranging solder paste on an attachment end and/or the attachment pad 606 may include any one or more materials, structures, arrangements, processes, and/or the like as described herein. Moreover, one or more proceeding or subsequent processes may also be implemented with respect to the arranging solder paste on an attachment end and/or the attachment pad 606 consistent with the disclosure.

In aspects, the arranging solder paste on an attachment end and/or the attachment pad 606 may include arranging solder paste on the attachment end 122 and/or the attachment pad 114 as described herein.

The process of forming leads on a device package 600 of the disclosure may include heating and reflowing the solder to connect the lead structure and/or the attachment end to the attachment pad 608. In this regard, the heating and reflowing the solder to connect the lead structure and/or the attachment end to the attachment pad 608 may include any one or more materials, structures, arrangements, processes, and/or the like as described herein. Moreover, one or more proceeding or subsequent processes may also be implemented with respect to the heating and reflowing the solder to connect the lead structure and/or the attachment end to the attachment pad 608 consistent with the disclosure. In aspects, the heating and reflowing the solder to connect the lead structure and/or the attachment end to the attachment pad 608 may include heating and reflowing the solder to connect the lead structure 112 and/or the attachment end 122 to the attachment pad 114 as described herein.

The following are a number of nonlimiting EXAMPLES of aspects of the disclosure.

One EXAMPLE: a device package includes a plurality of leads comprising lead structures configured as part of a leadframe during manufacturing. The device package in addition includes the plurality of leads includes attachment pads. The package moreover includes a lead alignment construction comprising one or more of the attachment pads being implemented with a solder mask material configured to promote alignment of all of the plurality of leads attached to the leadframe during solder reflow.

The above-noted EXAMPLE may further include any one or a combination of more than one of the following EXAMPLES: The device package of the above-noted EXAMPLE where the solder mask material at least partially surrounds an exposed metal area of one or more of the attachment pads adjacent an attachment end of the plurality of leads. The device package of the above-noted EXAMPLE where the solder mask material is configured with dimensions to promote an alignment of the plurality of leads to one or more of the attachment pads during solder reflow. The device package of the above-noted EXAMPLE where one or more of the attachment pads are configured with dimensions to promote an alignment of the plurality of leads during solder reflow. The device package of the above-noted EXAMPLE where the solder mask material is arranged along at least two sides of one or more of the attachment pads. The device package of the above-noted EXAMPLE where the solder mask material is arranged along three sides of one or more of the attachment pads. The device package of the above-noted EXAMPLE where the solder mask material is arranged such that there is an attachment area configured to receive solder for attachment of the plurality of leads to one or more of the attachment pads. The device package of the above-noted EXAMPLE where an arrangement of the solder mask material forms the attachment area on one or more of the attachment pads without any of the solder mask material arranged thereon. The device package of the above-noted EXAMPLE where one or more of the attachment pads comprise a first pad side, a second pad side, a third pad side, and a fourth pad side, which is arranged adjacent a device side; and where the solder mask material is arranged to extend from the second pad side to the first pad side adjacent the third pad side. The device package of the above-noted EXAMPLE where the solder mask material is further arranged to extend from the fourth pad side to the second pad side of one or more of the attachment pads adjacent the first pad side. The device package of the above-noted EXAMPLE where the solder mask material is further arranged to extend from the first pad side to the third pad side adjacent the second pad side. The device package of the above-noted EXAMPLE where the solder mask material is further arranged to extend from the fourth pad side to the second pad side of one or more of the attachment pads adjacent the first pad side; and where the solder mask material is further arranged to extend from the first pad side to the third pad side adjacent the second pad side. The device package of the above-noted EXAMPLE where an attachment area comprises an attach width comprising a distance between the second pad side and the fourth pad side without the solder mask material; and where the attach width is 10% 80% greater than a lead width. The device package of the above-noted EXAMPLE where one of the attachment pads is implemented without the solder mask material. The device package of the above-noted EXAMPLE where some of the plurality of leads are arranged on a device side; and where two inner implementations of the plurality of leads on the device side are implemented with the lead alignment construction. The device package of the above-noted EXAMPLE where at least one of the plurality of leads on the device side are implemented without the lead alignment construction. The device package of the above-noted EXAMPLE where a center one of the plurality of leads on the device side is implemented without the lead alignment construction. The device package of the above-noted EXAMPLE where some of the plurality of leads are arranged a device side; and where two outer implementations of the plurality of leads on the device side are implemented with the lead alignment construction. The device package of the above-noted EXAMPLE where at least one of the plurality of leads on the device side are implemented without the lead alignment construction. The device package of the above-noted EXAMPLE where a center one of the plurality of leads on the device side is implemented without the lead alignment construction. The device package of the above-noted EXAMPLE where at least one of the lead structures is narrower than another one of the lead structures. The device package of the above-noted EXAMPLE comprising a RF package, a RF amplifier package, a RF power amplifier package, a RF power transistor package, and/or a RF power amplifier transistor package. The device package of the above-noted EXAMPLE comprising one or more semiconductor devices and a support, where the one or more semiconductor devices are attached to the support. The device package of the above-noted EXAMPLE comprising a housing configured to substantially surround the one or more semiconductor devices, which are mounted on the support. The device package of the above-noted EXAMPLE where the one or more semiconductor devices comprise one or more of a wide band-gap semiconductor device, an ultra-wideband device, a GaN based device, a Metal Semiconductor Field-Effect Transistor (MESFET), a Metal Oxide Field Effect Transistor (MOSFET), a Junction Field Effect Transistor (JFET), a Bipolar Junction Transistor (BJT), an Insulated Gate Bipolar Transistor (IGBT), a high-electron-mobility transistor (HEMT), and/or a Wide Band Gap (WBG) semiconductor. The device package of the above-noted EXAMPLE comprising: an input network comprising one or more resistors, one or more capacitors, and/or one or more inductors; and an output network comprising one or more resistors, one or more capacitors, and/or one or more inductors. The device package of the above-noted EXAMPLE comprising a General-Purpose Broadband component, a Telecom component, a L-Band component, a S-Band component, a X-Band component, a C-Band component, a Ku-Band component, a Satellite Communications component, and/or a Doherty configuration.

One EXAMPLE: a process includes configuring a plurality of leads comprising lead structures as part of a leadframe during manufacturing. The process in addition includes configuring the plurality of leads with attachment pads. The process moreover includes configuring a lead alignment construction comprising one or more of the attachment pads being implemented with a solder mask material configured to promote alignment of all of the plurality of leads attached to the leadframe during solder reflow.

The above-noted EXAMPLE may further include any one or a combination of more than one of the following EXAMPLES: The process of the above-noted EXAMPLE where the solder mask material at least partially surrounds an exposed metal area of one or more of the attachment pads adjacent an attachment end of the plurality of leads. The process of the above-noted EXAMPLE where the solder mask material is configured with dimensions to promote an alignment of the plurality of leads to one or more of the attachment pads during solder reflow. The process of the above-noted EXAMPLE where one or more of the attachment pads are configured with dimensions to promote an alignment of the plurality of leads during solder reflow. The process of the above-noted EXAMPLE where the solder mask material is arranged along at least two sides of one or more of the attachment pads. The process of the above-noted EXAMPLE where the solder mask material is arranged along three sides of one or more of the attachment pads. The process of the above-noted EXAMPLE where the solder mask material is arranged such that there is an attachment area configured to receive solder for attachment of the plurality of leads to one or more of the attachment pads. The process of the above-noted EXAMPLE where an arrangement of the solder mask material forms the attachment area on one or more of the attachment pads without any of the solder mask material arranged thereon. The process of the above-noted EXAMPLE where one or more of the attachment pads comprise a first pad side, a second pad side, a third pad side, and a fourth pad side, which is arranged adjacent a device side; and where the solder mask material is arranged to extend from the second pad side to the first pad side adjacent the third pad side. The process of the above-noted EXAMPLE where the solder mask material is further arranged to extend from the fourth pad side to the second pad side of one or more of the attachment pads adjacent the first pad side. The process of the above-noted EXAMPLE where the solder mask material is further arranged to extend from the first pad side to the third pad side adjacent the second pad side. The process of the above-noted EXAMPLE where the solder mask material is further arranged to extend from the fourth pad side to the second pad side of one or more of the attachment pads adjacent the first pad side; and where the solder mask material is further arranged to extend from the first pad side to the third pad side adjacent the second pad side. The process of the above-noted EXAMPLE where an attachment area comprises an attach width comprising a distance between the second pad side and the fourth pad side without the solder mask material; and where the attach width is 10% 80% greater than a lead width. The process of the above-noted EXAMPLE where one of the attachment pads is implemented without the solder mask material. The process of the above-noted EXAMPLE where some of the plurality of leads are arranged on a device side; and where two inner implementations of the plurality of leads on the device side are implemented with the lead alignment construction. The process of the above-noted EXAMPLE where at least one of the plurality of leads on the device side are implemented without the lead alignment construction. The process of the above-noted EXAMPLE where a center one of the plurality of leads on the device side is implemented without the lead alignment construction. The process of the above-noted EXAMPLE where some of the plurality of leads are arranged a device side; and where two outer implementations of the plurality of leads on the device side are implemented with the lead alignment construction. The process of the above-noted EXAMPLE where at least one of the plurality of leads on the device side are implemented without the lead alignment construction. The process of the above-noted EXAMPLE where a center one of the plurality of leads on the device side is implemented without the lead alignment construction. The process of the above-noted EXAMPLE where at least one of the lead structures is narrower than another one of the lead structures. The process of the above-noted EXAMPLE comprising implementing the device package as a RF package, a RF amplifier package, a RF power amplifier package, a RF power transistor package, and/or a RF power amplifier transistor package. The process of the above-noted EXAMPLE includes providing one or more semiconductor devices and a support, where the one or more semiconductor devices are attached to the support. The process of the above-noted EXAMPLE includes providing a housing configured to substantially surround the one or more semiconductor devices, which are mounted on the support. The process of the above-noted EXAMPLE where the one or more semiconductor devices comprise one or more of a wide band-gap semiconductor device, an ultra-wideband device, a GaN based device, a Metal Semiconductor Field-Effect Transistor (MESFET), a Metal Oxide Field Effect Transistor (MOSFET), a Junction Field Effect Transistor (JFET), a Bipolar Junction Transistor (BJT), an Insulated Gate Bipolar Transistor (IGBT), a high-electron-mobility transistor (HEMT), and/or a Wide Band Gap (WBG) semiconductor. The process of the above-noted EXAMPLE comprising: providing an input network comprising one or more resistors, one or more capacitors, and/or one or more inductors; and providing an output network comprising one or more resistors, one or more capacitors, and/or one or more inductors. The process of the above-noted EXAMPLE comprising implementing the device package as a General-Purpose Broadband component, a Telecom component, a L-Band component, a S-Band component, a X-Band component, a C-Band component, a Ku-Band component, a Satellite Communications component, and/or a Doherty configuration.

Accordingly, the disclosure has set forth a device and process to reduce misalignment between pads and leads. In particular, a device package having pads configured to promote self alignment of leads; and a process of implementing a device package having pads configured to promote self alignment of the leads.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The many features and advantages of the disclosure are apparent from the detailed specification, and, thus, it is intended by the appended claims to cover all such features and advantages of the disclosure which fall within the true spirit and scope of the disclosure. Further, since numerous modifications and variations will readily occur to those skilled in the art, it is not desired to limit the disclosure to the exact construction and operation illustrated and described, and, accordingly, all suitable modifications and equivalents may be resorted to that fall within the scope of the disclosure.

1. A device package configured with a lead alignment construction, the device package comprising:
a plurality of leads comprising lead structures configured as part of a leadframe during manufacturing;
the plurality of leads further comprising attachment pads; and
a lead alignment construction comprising one or more of the attachment pads being implemented with a solder mask material configured to promote alignment of all of the plurality of leads attached to the leadframe during solder reflow.

2. The device package according to claim 1 wherein the solder mask material at least partially surrounds an exposed metal area of one or more of the attachment pads adjacent an attachment end of the plurality of leads.

3. The device package according to claim 1 wherein the solder mask material is configured with dimensions to promote an alignment of the plurality of leads to one or more of the attachment pads during solder reflow.

4. The device package according to claim 1 wherein one or more of the attachment pads are configured with dimensions to promote an alignment of the plurality of leads during solder reflow.

5. The device package according to claim 1 wherein the solder mask material is arranged along at least two sides of one or more of the attachment pads.

6. (canceled)

7. The device package according to claim 1 wherein the solder mask material is arranged such that there is an attachment area configured to receive solder for attachment of the plurality of leads to one or more of the attachment pads.

8. The device package according to claim 7 wherein an arrangement of the solder mask material forms the attachment area on one or more of the attachment pads without any of the solder mask material arranged thereon.

9. The device package according to claim 1 wherein one or more of the attachment pads comprise a first pad side, a second pad side, a third pad side, and a fourth pad side, which is arranged adjacent a device side; and
wherein the solder mask material is arranged to extend from the second pad side to the first pad side adjacent the third pad side.

10. The device package according to claim 9 wherein the solder mask material is further arranged to extend from the fourth pad side to the second pad side of one or more of the attachment pads adjacent the first pad side.

11. The device package according to claim 9 wherein the solder mask material is further arranged to extend from the first pad side to the third pad side adjacent the second pad side.

12. The device package according to claim 9 wherein the solder mask material is further arranged to extend from the fourth pad side to the second pad side of one or more of the attachment pads adjacent the first pad side; and
wherein the solder mask material is further arranged to extend from the first pad side to the third pad side adjacent the second pad side.

13. The device package according to claim 9
wherein an attachment area comprises an attach width comprising a distance between the second pad side and the fourth pad side without the solder mask material; and wherein the attach width is 10%-80% greater than a lead width.

14. The device package according to claim 1 wherein one of the attachment pads is implemented without the solder mask material.

15. The device package according to claim 1
wherein some of the plurality of leads are arranged on a device side; and
wherein two inner implementations of the plurality of leads on the device side are implemented with the lead alignment construction.

16. The device package according to claim 15 wherein at least one of the plurality of leads on the device side are implemented without the lead alignment construction.

17. The device package according to claim 15 wherein a center one of the plurality of leads on the device side is implemented without the lead alignment construction.

18.-20. (canceled)

21. The device package according to claim 1 wherein at least one of the lead structures is narrower than another one of the lead structures.

22. The device package according to claim 1 comprising a RF package, a RF amplifier package, a RF power amplifier package, a RF power transistor package, and/or a RF power amplifier transistor package.

23. The device package according to claim 1 comprising one or more semiconductor devices and a support, wherein the one or more semiconductor devices are attached to the support.

24.-27. (canceled)

28. A process of implementing a device package with a lead alignment construction, the process comprising:
configuring a plurality of leads comprising lead structures as part of a leadframe during manufacturing;
configuring the plurality of leads with attachment pads; and
configuring a lead alignment construction comprising one or more of the attachment pads being implemented with a solder mask material configured to promote alignment of all of the plurality of leads attached to the leadframe during solder reflow.

29.-54. (canceled)
